(19) United States
(12) Patent Application Publication
(10) Pub. No.: US 2010/0012356 A1
(43) Pub. Date: Jan. 21, 2010

(54) PRINTED WIRING BOARD HAVING RECOGNITION MARK

(75) Inventor: Kenji Hasegawa, Hamura-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/464,441

(22) Filed: May 12, 2009

(30) Foreign Application Priority Data
Jul. 17, 2008 (JP) 2008-186318

(51) Int. Cl. H05K 1/02

(52) U.S. Cl. 174/255

(57) ABSTRACT

According to one embodiment, a printed wiring board comprises an insulating substrate having a mounting surface, a recognition mark formed on the mounting surface of the insulating substrate, and a plurality of reinforcing patterns formed on the mounting surface of the insulating substrate. The reinforcing patterns extend from an outer periphery of the recognition mark toward outside of the recognition mark and are arranged circumferentially at intervals relative to the recognition mark. Each of the reinforcing patterns has a width less than a width of a part of the outer periphery of the recognition mark connecting adjacent ones of the reinforcing patterns.

### CROSS-REFERENCE TO RELATED APPLICATIONS

This application is based upon and claims the benefit of priority from Japanese Patent Application No. 2008-186318, filed Jul. 17, 2008, the entire contents of which are incorporated herein by reference.

### BACKGROUND

1. Field

One embodiment of the invention relates to a printed wiring board having a recognition mark used as a reference for determining the position of the printed wiring board or a surface mounting device.

2. Description of the Related Art

A printed wiring board applied to an electronic apparatus has a recognition mark called a “fiducial mark”. This recognition mark includes the following two types: a recognition mark for determining the position of the printed wiring board itself when solder cream is printed on a printed wiring board, for example; and a recognition mark for determining the position of a surface mounting device with respect to a printed wiring board. The recognition mark can be read by an image recognition device such as a CCD camera.

The conventional recognition mark is formed on a mounting surface of a printed wiring board along with a plurality of conductive patterns. The recognition mark is a small pattern used as a reference in positioning the printed wiring board and a surface mounting device, and is separated from the conductive patterns such that the recognition mark is independent on the mounting surface. Further, the recognition mark is exposed to the mounting surface without being covered by solder resist such that the recognition mark can be accurately read by an, image recognition device.

As a result, when a plurality of printed wiring boards are rubbed against one another in the process of manufacturing the printed circuit boards, for example, recognition marks, which are small dots, easily peel off from mounting surfaces. When the recognition marks peel off from the mounting surfaces, it becomes difficult for an image recognition device to read the recognition marks, which affects the operations of positioning printed wiring boards and surface mounting devices.

Further, since the recognition marks are small dots independent of conductive patterns, it is very difficult to detect whether the recognition marks have peeled off by means of an electrical test. In the past, a visual appearance test was required to check whether the recognition mark had peeled off or not by inspection of the printed wiring board by a technician. Such a visual appearance test necessarily involves variance in test result. This results in erroneous shipping of defective goods from which recognition marks have peeled off or reduced yields at the time of manufacturing the printed wiring boards.

In order to cope with these problems, in the printed wiring board disclosed in Jpn. Pat. Appln. KOKAI Publication No. 8-250825, a recognition mark positioned on a mounting surface is formed of a central mark to be read and a guard pattern surrounding the central mark. The guard pattern is intended to protect the central mark and has a height from the mounting surface greater than that of the central mark.

However, the guard pattern merely surrounds the central mark, and does not enhance the attachment of the central mark to the mounting surface. When power to peel off the central mark from the mounting surface is applied to the printed wiring board, the effect of preventing the central mark from peeling off cannot be expected.

In the printed wiring board disclosed in FIG. 6 of Jpn. Pat. Appln. KOKAI Publication No. 2007-258374, one plated lead extends from a recognition mark formed on a mounting surface. The plated lead is formed on the mounting surface along with the recognition mark and a conductive pattern. The plated lead electrically connects the recognition mark and the conductive pattern.

However, the plated lead is continuous to only one part of the outer periphery of the recognition mark. Moreover, the plated lead has a width far narrower than the diameter of the recognition mark. It is therefore difficult to enhance the attachment of the recognition mark by means of only one plated lead, and the effect of preventing the recognition mark from peeling off cannot be expected.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a plan view of an exemplary printed wiring board according to a first embodiment of the present invention;

FIG. 2 is an exemplary plan view showing a state in which a plurality of recognition marks, a plurality of pads, and a ground pattern are formed on a mounting surface of an insulating substrate according to the first embodiment of the present invention;

FIG. 3 is an exemplary plan view showing the relationship between the first recognition mark and the solder resist film according to the first embodiment of the present invention;

FIG. 4 is an exemplary plan view showing the positional relationship between the first recognition mark and the ground pattern according to the first embodiment of the present invention;

FIG. 5 is an exemplary cross-sectional view along line F5-F5 of FIG. 3;

FIG. 6 is a plan view of an exemplary printed wiring board according to a second embodiment of the present invention;

FIG. 7 is a plan view of an exemplary printed wiring board according to a third embodiment of the present invention;

FIG. 8 is an exemplary side view of a printed wiring board in which a part of an insulating substrate is shown in the cross-sectional direction according to a fourth embodiment of the present invention;

FIG. 9 is an exemplary plan view showing the shape of the recognition mark having reinforcing patterns according to a fifth embodiment of the present invention; and

FIG. 10 is an exemplary plan view showing the shape of the recognition mark having reinforcing patterns according to a sixth embodiment of the present invention.

### DETAILED DESCRIPTION

Various embodiments according to the invention will be described hereinafter with reference to the accompanying drawings. In general, according to one embodiment of the invention, a printed wiring board comprises an insulating substrate having a mounting surface, a recognition mark formed on the mounting surface of the insulating substrate, a plurality of reinforcing patterns formed on the mounting surface of the insulating substrate. The reinforcing patterns extend from an outer periphery of the recognition mark toward the outside of the recognition mark and are arranged circumferentially at intervals relative to the recognition mark. Each of the reinforcing patterns has a width less than a length of a part of the outer periphery of the recognition mark connecting adjacent ones of the reinforcing patterns.

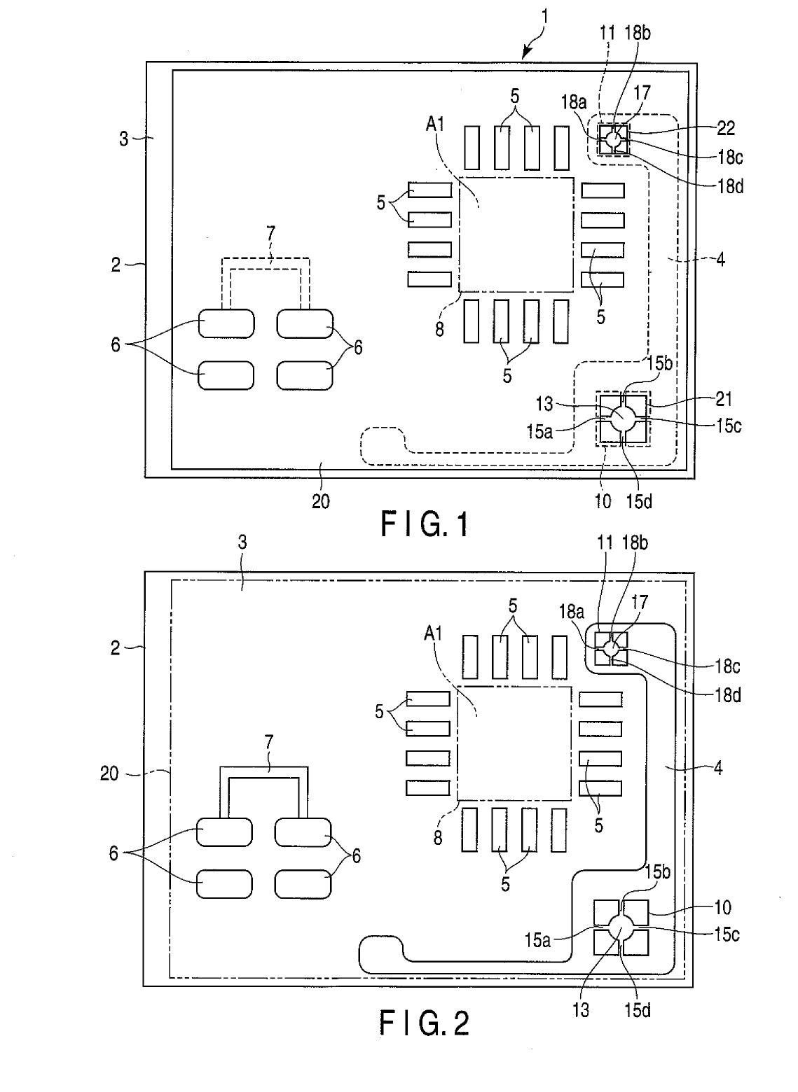

The first embodiment of the present invention will now be described with reference to FIGS. 1-5.

FIGS. 1 and 2 show examples of a printed wiring board 1 used for an electronic apparatus such as a portable computer. The printed wiring board 1 comprises an insulating substrate 2 used as a base. The insulating substrate 2 has a flat mounting surface 3. A ground pattern 4, a plurality of connection pads 5, a plurality of electrode pads 6, and a conductive pattern 7 are formed on the mounting surface 3. The ground pattern 4, the connection pads 5, the electrode pads 6, and the conductive pattern 7 are formed of copper foil, for example. The copper foil is attached on the mounting surface 3 of the insulating substrate 2.

The ground pattern 4 is a plane pattern which is a kind of conductive layer, and extends in a planar form over a predetermined range on the mounting surface 3. The connection pads 5 are arranged to surround a device mounting region A1 defined on the mounting surface 3. The device mounting region A1 has a rectangular shape corresponding to the shape of a surface mounting device 8, such as a semiconductor package. The connection pads 5 are arranged at intervals around the four corners of the device mounting region A1.

The electrode pads 6 are separated from the ground pattern 4 and the connection pads 5 on the mounting surface 3. The conductive pattern 7 electrically connects two adjacent ones of the electrode pads 6.

As shown in FIGS. 1 and 2, the ground pattern 4 includes a first opening region 10 and a second opening region 11. Each of the first and second opening regions 10, 11 has a rectangular shape defined by the four edges of the ground pattern 4. The mounting surface 3 is exposed in the opening regions 10, 11. According to the present embodiment, the first opening region 10 is positioned in the vicinity of a corner part of the insulating substrate 2, and the second opening region 11 is positioned in the vicinity of the device mounting region A1.

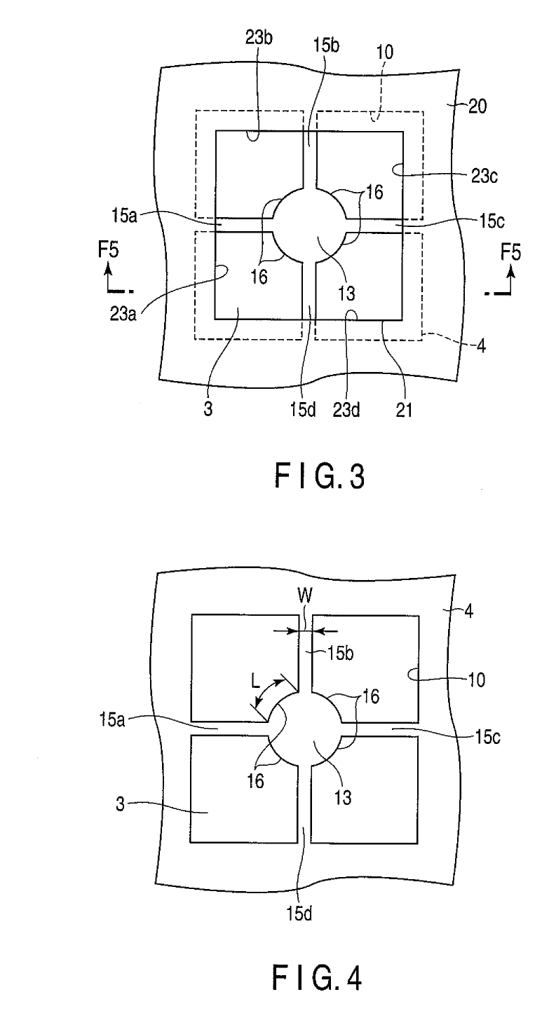

A first recognition mark 13 is arranged in the first opening region 10 of the ground pattern 4. The first recognition mark 13 is intended to position the printed wiring board 1 when solder cream is printed on the connection pads 5, and the electrode pads 6, for example, and is read by an image recognition device 14 such as a CCD camera. The first recognition mark 13 is formed of copper foil attached to the mounting surface 3. As shown in FIGS. 3 and 4, the first recognition mark 13 has a circular pattern shape cut off to be independent of the ground pattern 4.

Four reinforcing patterns 15a, 15b, 15c, 15d are formed on the mounting surface 3 exposed to the first opening region 10. The reinforcing patterns 15a, 15b, 15c, 15d are formed by copper foils attached to the mounting surface 3.

The reinforcing patterns 15a, 15b, 15c, 15d lineally extend toward the edges of the first opening region 10 from the outer periphery of the first recognition mark 13, and arranged circumferentially at intervals of 90° relative to the recognition mark 13. In other words, the reinforcing patterns 15a, 15b, 15c, 15d radially project toward the radial direction of the first recognition mark 13 from the first recognition mark 13.

The projecting ends of the reinforcing patterns 15a, 15b, 15c, 15d are continuous to the four edges of the ground pattern 4 defining the first opening region 10. The reinforcing patterns 15a, 15b, 15c, 15d are integrally formed with the first recognition mark 13 and the ground pattern 4 and function as conductive patterns for bringing the first recognition mark 13 and the ground pattern 4 into electrical conduction.

As best illustrated in FIGS. 3 and 4, the first recognition mark 13 includes four circular-arc sections 16 which connect adjacent ones of the reinforcing patterns 15a, 15b, 15c, 15d. Each of the circular-arc sections 16 has a length L circumferentially relative to the first recognition mark 13. The length L of each of the circular-arc sections 16 is equal. Each of the reinforcing patterns 15a, 15b, 15c, 15d has a width W along the direction crossing the direction in which each of the reinforcing patterns 15a, 15b, 15c, 15d projects. The widths W of each of the reinforcing patterns 15a, 15b, 15c, 15d are equal and less than the length L of each of the circular-arc sections 16. Thereby, the length L of the circular-arc sections 16 can be secured sufficiently. Therefore, although the four reinforcing patterns 15a, 15b, 15c, 15d project radially from the outer periphery of the first recognition mark 13, the unique form of the first recognition mark 13 is clarified.

As shown in FIGS. 1 and 2, a second recognition mark 17 is arranged in the second opening region 11 of the ground pattern 4. The second recognition mark 17 is used to position the device mounting region A1 and the surface mounting device 8 when the surface mounting device 8 is mounted on the device mounting region A1 of the printed wiring board 1, and is read by the image recognition device 14.

The basic configuration of the second recognition mark 17 is the same as that of the first recognition mark 13, except for that the second recognition mark 17 is smaller than the first recognition mark 13. Further, the second recognition mark 17 has four radially projecting reinforcing patterns 18a, 18b, 18c, 18d. Each of the reinforcing patterns 18a, 18b, 18c, 18d has a configuration same as that of the reinforcing patterns 15a/15b, 15c, 15d of the first recognition mark 13. Therefore, in the present embodiment, detailed description of the second recognition mark 17 and the reinforcing patterns 18a, 18b, 18c, 18d will be omitted.

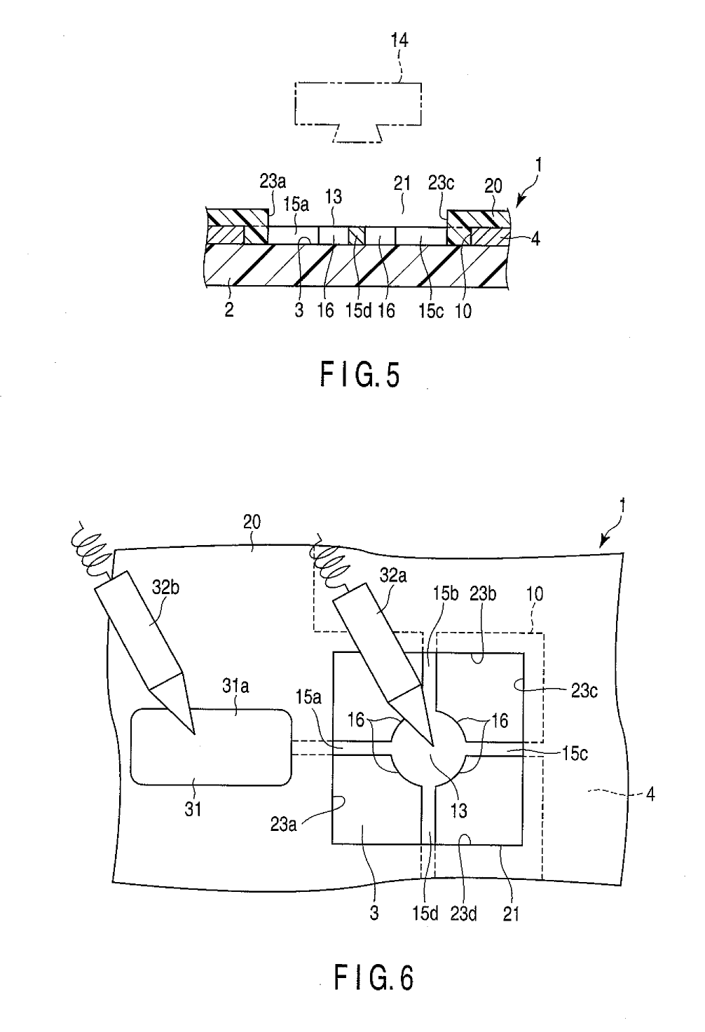

As shown in FIGS. 1 and 5, a solder resist film 20 is stacked on the mounting surface 3 of the insulating substrate 2. The solder resist film 20 covers the mounting surface 3 and the ground pattern 4. The connection pads 5 and the electrode pads 6 are exposed outside the printed wiring board 1 without being covered by the solder resist film 20.

The solder resist film 20 includes a first opening part 21 which exposes the first recognition mark 13 and a second opening part 22 which exposes the second recognition mark 17. The basic configurations of the first opening part 21 and the second opening part 22 are the same except for the size. In the present embodiment, the first opening part 21 will be described as an example, and the description of the second opening part 22 will be omitted.

As shown in FIG. 3, the first opening part 21 has a rectangular opening shape smaller than the first opening region 10 of the ground pattern 4. The solder resist film 20 includes four edge parts 23a, 23b, 23c, 23d defining the first opening part 21. The edge parts 23a, 23b, 23c, 23d surround the first recognition mark 13 in positions apart from the outer periphery of the first recognition mark 13. In other words, the edge parts 23a, 23b, 23c, 23d are arranged around the four edges defining the first opening region 10 and continuously cover the edges.

The edges 23a, 23b, 23c, 23d of the solder resist film 20 cross over the projection ends of the reinforcing patterns 15a, 15b, 15c, 15d. Thus, the connection part of the reinforcing patterns 15a, 15b, 15c, 15d and the ground pattern 4 is covered by the solder resist film 20.

According to the first embodiment of the present invention, the four reinforcing patterns 15a, 15b, 15c, 15d radially projecting from the outer periphery of the first recognition mark 13 are attached to the mounting surface 3 along with the first recognition mark 13. Thus, the attachment of the first recognition mark 13 to the mounting surface 3 can be evenly reinforced in the four parts circumferentially relative to the first recognition mark 13. Thereby, the first recognition mark 13 is prevented from easily peeling off from the mounting surface 3.

According to the present embodiment, in particular, since the reinforcing patterns 15a, 15b, 15c, 15d are integrally connected to the ground pattern 4, the projection ends of the reinforcing patterns 15a, 15b, 15c, 15d are prevented from easily peeling off from the mounting surface 3.

Further, the connection parts connecting the reinforcing patterns 15a, 15b, 15c, 15d and the ground pattern 4 are covered by the solder resist film 20. Thereby, the solder resist film 20 keeps the reinforcing patterns 15a, 15b, 15c, 15d on the mounting surface 3 such that the reinforcing patterns 15a, 15b, 15c, 15d are not separated from the mounting surface 3. As a result, the attachment of the reinforcing patterns 15a, 15b, 15c, 15d to the mounting surface 3 is improved and the first recognition mark 13 can be reliably maintained in a normal position on the mounting surface 3 such that the first recognition mark 13 does not peel off from the mounting surface 3.

Further, since the second recognition mark 17 includes four radially projecting reinforcing patterns 18a, 18b, 18c, 18d, the attachment of the second recognition mark 17 can be enhanced using the reinforcing patterns 18a, 18b, 18c, 18d, and the second recognition mark 17 can be prevented from peeling off.

In addition, according to the above-described configuration, since the width W of each of the reinforcing patterns 15a, 15b, 15c, 15d is less than the length L of the circular-arc part 16 of the first recognition mark 13, the length L of the circular-arc part 16 can be sufficiently secured. Thereby, the unique shape of the first recognition mark 13 is clearly defined although the four reinforcing patterns 15a, 15b, 15c, 15d radially project from the outer periphery of the first recognition mark 13. As a result, the first recognition mark 13 can be reliably recognized by the image recognition device 14, and the position of the printed wiring board 1 can be determined accurately.

The reinforcing patterns 18a, 18b, 18c, 18d of the second recognition mark 17 has the same configuration as that of the reinforcing patterns 15a, 15b, 15c, 15d of the first recognition mark 13. Thereby, relative positioning of the device mounting region A1 and the surface mounting device 8 can be performed accurately without losing the recognition property of the second recognition mark 17.

The present invention is not limited to the first embodiment and can be modified within the range of not departing from the spirit of the invention. For example, a plurality of first recognition marks and a plurality of second recognition marks may be arranged on the mounting surface of the printed wiring board. That is, the number of the first and second recognition marks may be changed according to the actual pattern configuration of the printed wiring board. Each of the plurality of first recognition marks and the plurality of second recognition marks should preferably include a plurality of reinforcing patterns.

Further, the insulating substrate forming the printed wiring board can be obtained by cutting the base panel of a predetermined size into a specific size. In this case, when enough space to arrange recognition marks does not exist in the piece cut from the base panel and becomes an actual product, a recognition mark may be arranged on the remaining part of the base panel which becomes waste. The same configuration as described in the first embodiment is also applied to the recognition marks arranged on the waste.

FIG. 6 shows the second embodiment of the present invention.

The second embodiment is different from the first embodiment in that whether the first recognition mark 13 has peeled off from the mounting surface 3 or not is detected by an electrical test.

As shown in FIG. 6, a test pad 31 having conductivity is formed on a mounting surface 3. The test pad 31 is an example of a conductive layer, and is adjacent to the first recognition mark 13 in a position different from that of the ground pattern 4. The test pad 31 has a contact surface 31a exposed to the outside of the solder resist film 20 without being covered by the solder resist film 20.

Further, one reinforcing pattern 15a included in the four reinforcing patterns 15a, 15b, 15c, 15d projecting from the first recognition mark 13 is electrically connected to the test pad 31.

In an electrical test of detecting peeling of the first recognition mark 13, a test device having a pair of test probes 32a, 32b is used. The test probe 32a, which is one of the pair of test probes, corresponds to the first recognition mark 13, and the test probe 32b, which is the other one of the pair of test probes, corresponds to the test pad 31. When the printed wiring board 1 to be tested is mounted on the test device, the test probe 32a, which is one of the pair of probes, contacts the first recognition mark 13, and the test probe 32b, which is the other one of the test probes, contacts the test pad 31.

The test device checks electrical conductivity between one of the test probe 32a, which is one of the test probes, and the test probe 32b, which is the other one of the test probes, and electrically detects whether the first recognition mark 13 has peeled off from the mounting surface 3 or not.

More specifically, when the test probe 32a, which is one of the test probes, and the test probe 32b, which is the other one of the test probes, are brought into conduction, the test device determines that the first recognition mark 13 is kept in a normal position on the mounting surface 3, and has not peeled off from the mounting surface 3. On the other hand, when the test probe 32a, which is one of the test probes, and the test probe 32b, which is the other one of the test probes, are out of conduction, the test device assumes that the first recognition mark 13 does not exist in the normal position, and has peeled off from the mounting surface 3. Further, when the test probe 32a, which is one of the test probes, and the test probe 32b, which is the other one of the test probes, are out of conduction, the test device determines that the printed wiring board 1 to be tested is a defective, even though the first recognition mark 13 has not peeled off from the mounting surface 3.

Thereby, as compared to human appearance test in which the printed wiring board 1 is observed by a person, higher reliability of the determined result can be obtained. This prevents defective products from being shipped mistakenly and suppresses decrease in yields at the time of manufacturing the printed wiring board 1.

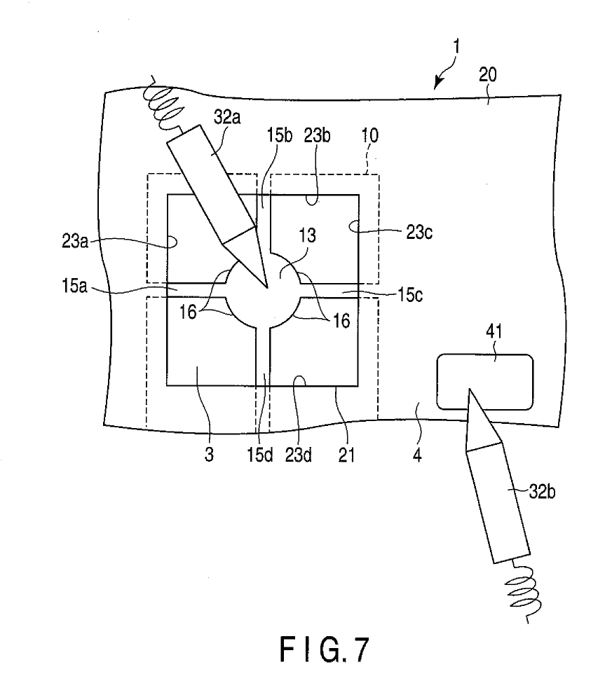

FIG. 7 discloses the third embodiment of the present invention.

The third embodiment is different from the second embodiment in that electrical conduction between a first recognition mark 13 and a ground pattern 4 is checked.

As shown in FIG. 7, four reinforcing patterns 15a, 15b, 15c, 15d radially projecting from the first recognition mark 13 are electrically connected to the ground pattern 4 as in the first embodiment. The ground pattern 4 has a contact surface 41 exposed to the outside of a solder resist film 20 without being covered by the solder resist film 20. The contact surface 41 of the ground pattern 4 forms a test pad.

According to the third embodiment, a test probe 32b of the test device corresponds to the contact surface 41 of the ground pattern 4. When the printed wiring board 1 to be tested is mounted on the test device, a test probe 32a, which is one of a pair of test probes, contacts the first recognition mark 13, and the test probe 32b, which is the other one of the pair of test probes, contacts the contact surface 41.

By causing the test device to check electrical conduction between the test probe 32a, which is one of the test probes, and the test probe 32b, which is the other one of the test probes, whether the first recognition mark 13 has peeled off from the mounting surface 3 or not can be electrically detected.

In the second and third embodiments, peeling of the first recognition mark for positioning the printed wiring board is electrically detected, but the present invention is not limited thereto. For example, whether a second recognition mark for positioning a device mounting region and a surface mounting device has peeled off or not can be electrically detected by an electrical test using a similar test device.

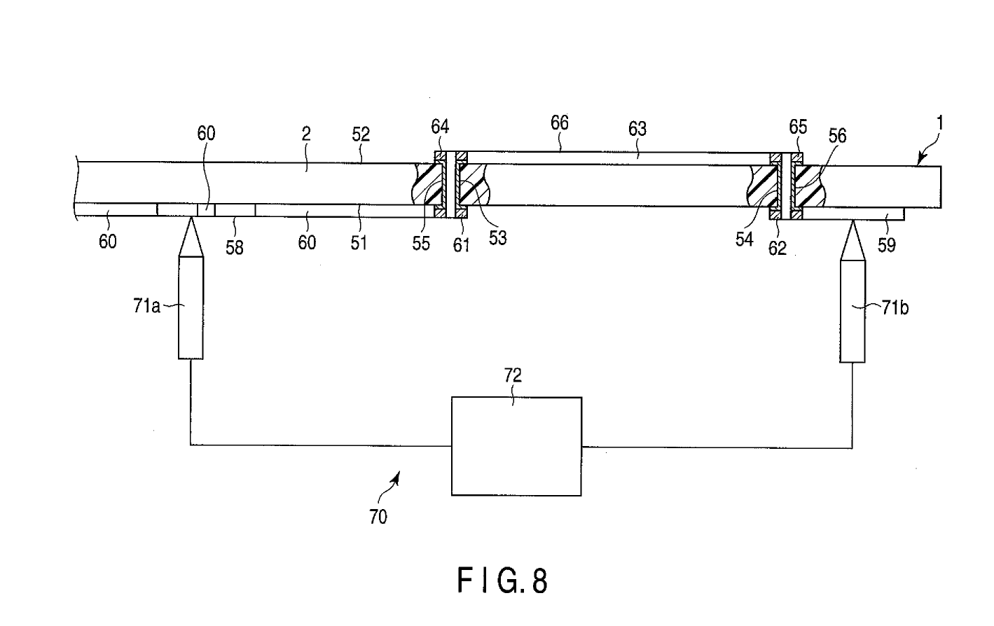

FIG. 8 discloses the fourth embodiment of the present invention.

The fourth embodiment is different from the first embodiment in configuration of a printed wiring board 1 to be tested. As shown in FIG. 8, an insulating substrate 2 of the printed wiring board 1 has a first mounting surface 51 and a second mounting surface 52. The second mounting surface 52 is positioned opposite to the first mounting surface 51.

A first conductive through hole 53 and a second conductive through hole 54 are formed in the insulating substrate 2. The first and second conductive through holes 53, 54 are made in a first mounting surface 51 and a second mounting surface 52 of the insulating substrate 2 in positions apart from each other. The first conductive through hole 53 has a plated layer 55. The plated layer 55 is exposed to the first mounting surface 51 and the second mounting surface 52. Similarly, the second conductive through hole 54 has a plated layer 56. The plated layer 56 is exposed to the first mounting surface 51 and the second mounting surface 52.

A recognition mark 58 and a test pad 59 are formed on the first mounting surface 51. The recognition mark 58 is read by an image recognition device, not shown, at the time of positioning of the printed wiring board 1, for example, and is formed of copper foil attached to the first mounting surface 51. The recognition mark 58 has a plurality of reinforcing patterns 60. The reinforcing patterns 60 are formed of copper foil attached to the first mounting surface 51 and radially project from the outer periphery of the recognition mark 58. The width of each of the reinforcing patterns 60 is less than the length of a part of the outer periphery of the recognition mark 58 connecting adjacent ones of the reinforcing patterns 60. That is, the relationship between the width of the reinforcing patterns 60 and the length of the part of the outer periphery of the recognition mark 58 is the same as that of the first embodiment.

A land 61 is formed in the reinforcing pattern 60, which is one of the reinforcing patterns. The land 61 fits into the first conductive through hole 53 made in the first mounting surface 51 and is soldered to the plated layer 55.

The test pad 59 is an example of the first conductive layer and is apart from the recognition mark 58. A land 62 is formed at an end part of the test pad 59. The land 62 fits into the second conductive through hole 54 made in the first mounting surface 51 and soldered to the plated layer 56.

A wiring pattern 63 is formed on the second mounting surface 52. The wiring pattern 63 is an example of the second conductive layer. A land 64 is formed at one end of the wiring pattern 63. The land 64 fits into the first conductive through hole 53 made in the second mounting surface 52 and is soldered to the plated layer 55. Further, a land 65 is formed at the other end of the wiring pattern 63. The land 65 fits into the second conductive through hole 54 made in the second mounting surface 52 and is soldered to the plated layer 56. The reinforcing pattern 60, which is one of the reinforcing patterns, the first conductive through hole 53, the second conductive through hole 54 and the wiring pattern 63 form a conductive path 66 electrically connecting the recognition mark 58 and the test pad 59.

In the fourth embodiment, whether the recognition mark 58 has peeled off from the first mounting surface 51 or not is electrically detected. A test device 70 used for this detection includes a pair of test probes 71a, 71b and a tester 72. The test probe 71a, which is one of the test probes, corresponds to the recognition mark 58, and the test probe 71b, which is the other one of the test probes, corresponds to the test pad 59. When the printed wiring board 1 to be tested is mounted on the test device 70, the test probe 71a, which is one of the test probes, contacts the recognition mark 58, and the test probe 71b, which is the other one of the test probes, contacts the test pad 59.

The test device 70 checks electrical conduction between the test probe 71a, which is one of the test probes, and the test probe 71b, which is the other one of the test probes, using the tester 72. Thereby, whether the recognition mark 58 has peeled off from the first mounting surface 51 or not can be electrically detected.

In the fourth embodiment, the test pad can be replaced with other recognition marks. Thereby, whether a plurality of recognition marks have defects or not can be electrically detected.

According to the fourth embodiment, the land 61 is formed in the reinforcing pattern 60 projecting from the recognition mark 58. The land 61 is fixed by means of solder, for example, to the plated layer 55 of the first conductive through hole 53. Thereby, the attachment of the reinforcing pattern 60 which is one of the reinforcing patterns to the first mounting surface 51 can be enhanced by the land 61.

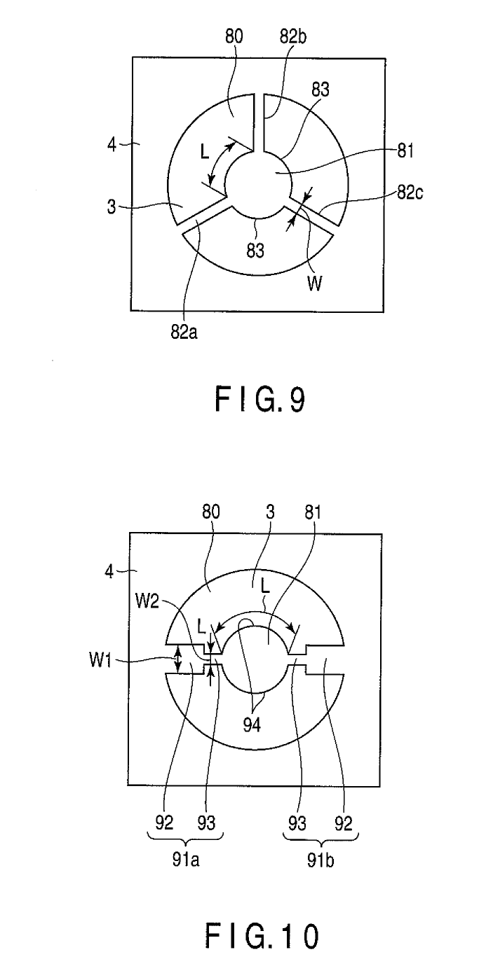

FIG. 9 shows the fifth embodiment of the present invention.

In the fifth embodiment, a ground pattern 4 has a circular opening region 80. A circular recognition mark 81 and three reinforcing patterns 82a, 82b, 82c are formed on a mounting surface 3 exposed from the opening region 80. The recognition mark 81 and the reinforcing patterns 82a, 82b, 82c are formed of copper foil attached to the mounting surface 3. The reinforcing patterns 82a, 82b, 82c lineally extend toward the edges of the opening region 80 from the outer periphery of the recognition mark 81 and arranged circumferentially at intervals of 120° relative to the recognition mark 81.

The recognition mark 81 has three circular-arc parts 83 connecting adjacent ones of reinforcing patterns 82a, 82b, 82c. Each of the circular-arc parts 83 has a length L circumferentially relative to the recognition mark 81. The length L of each of the circular-arc parts 83 is equal. Each of the reinforcing patterns 82a, 82b, 82c has a width W along the direction crossing the projection direction of the reinforcing patterns 82a, 82b, 82c. The widths W of each of the reinforcing patterns 82a, 82b, 82c are equal and formed less than the length L of each of the circular-arc parts 83.

With this configuration, the attachment of the recognition mark 81 to the mounting surface 3 can be evenly reinforced in three parts circumferentially relative to the recognition mark 81. As a result, the recognition mark 81 is prevented from easily peeling off from the mounting surface 3.

FIG. 10 discloses the sixth embodiment of the present invention.

In the sixth embodiment, a pair of reinforcing patterns 91a, 91b project from the outer periphery of a recognition mark 81. The reinforcing patterns 91a, 91b face each other radially relative to the recognition mark 81 and lineally connect the outer periphery of the recognition mark 81 and the edges of the opening region 80 of a ground pattern 4.

Each of the reinforcing patterns 91a, 91b has a first part 92 and a second part 93. The first part 92 is continuous to the ground pattern 4 and has a first width W1. The second part 93 is continuous to the recognition mark 81 and has a second width W2. The second width W2 is less than the first width W1.

The recognition mark 81 has two circular-arc parts 94 connecting the adjacent reinforcing patterns 91a, 91b. Each of the circular-arc parts 94 has a length L circumferentially relative to the recognition mark 81. The length L of each of the circular-arc parts 94 is equal. The width W2 of the second part 93 of each of the reinforcing patterns 91a, 91b is formed less than the length L of each of the circular-arc parts 94.

With this configuration, the attachment of the recognition mark 81 to the mounting surface 3 can be evenly reinforced in two parts separated from each other circumferentially relative to the recognition mark 81. Thereby, the recognition mark 81 is prevented from easily peeling off from the mounting surface 3.

In the present invention, the shape of the recognition mark is not limited to a circular shape. The recognition mark only needs to be read by an image reading device and may be rectangular or polygonal, for example.

While certain embodiments of the inventions have been described, there embodiments have been presented by way of example only, and are not intended to limit the scope of the invention. Indeed, the novel methods and systems described herein may be embodied in a variety of other forms; furthermore various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed wiring board comprising:
an insulating substrate comprising a mounting surface;
a fiduciary marker on the mounting surface of the insulating substrate; and
a plurality of reinforcing patterns on the mounting surface of the insulating substrate, the reinforcing patterns extending from an outer periphery of the fiduciary marker toward outside of the fiduciary marker and located circumferentially at intervals relative to the fiduciary marker, wherein each of the reinforcing patterns has a width shorter than a length of a portion of the outer periphery of the fiduciary marker connecting to adjacent reinforcing patterns.

2. The printed wiring board of claim 1, wherein the fiduciary marker and the reinforcing patterns are attached to the mounting surface.

3. The printed wiring board of claim 2, further comprising a resist film on the mounting surface of the insulating substrate and over at least a portion of the reinforcing patterns, the resist film comprising an opening portion comprising the fiduciary marker.

4. The printed wiring board of claim 3, wherein the resist film comprises an edge portion which is the opening portion, the edge portion surrounding the fiduciary marker in a position apart from the fiduciary marker.

5. The printed wiring board of claim 3, wherein the edge portion of the resist film is configured to cover the reinforcing patterns.

6. The printed wiring board of claim 1, wherein the reinforcing patterns radially extend from the fiduciary marker.

7. The printed wiring board of claim 6, wherein the fiduciary marker and the reinforcing patterns comprise a conductive material.

8. The printed wiring board of claim 7, further comprising a conductive layer on a mounting surface of the insulating substrate, the conductive layer being apart from the fiduciary marker on the mounting surface and electrically connected to the fiduciary marker via the reinforcing patterns.

9. A printed wiring board comprising:
an insulating substrate comprising a mounting surface;
a conductive layer on the mounting surface of the insulating substrate;
a fiduciary marker on the mounting surface of the insulating substrate, the fiduciary marker comprising conductivity and being separated from the conductive layer; and
a plurality of conductive patterns on the mounting surface of the insulating substrate, the conductive patterns extending from an outer periphery of the fiduciary marker toward outside of the fiduciary marker, being located circumferentially at intervals relative to the fiduciary marker, and configured to connect the fiduciary marker and the conductive layer, each of the conductive patterns comprising a width shorter than a length of a portion of the outer periphery of the fiduciary marker connecting adjacent conductive patterns.

10. The printed wiring board of claim 9, wherein the fiduciary marker and the conductive patterns are attached to the mounting surface.

11. The printed wiring board of claim 9, further comprising a resist film on the mounting surface of the insulating substrate, and over at least a portion of the conductive patterns.

12. The printed wiring board of claim 11, wherein connecting portions between the conductive layer and the conductive patterns are under the resist film.

13. The printed wiring board of claim 11, wherein at least a portion of the conductive layer is a test pad exposed to outside of the resist film without being under the resist film.

14. A printed wiring board comprising:
an insulating substrate comprising a first mounting surface, a second mounting surface opposite to the first mounting surface, a first conductive through hole in the first mounting surface and the second mounting surface, and a second conductive through hole in the first mounting surface and the second mounting surface in a position apart from the first conductive through hole;
a fiduciary marker on the first mounting surface of the insulating substrate and comprising conductivity;
a plurality of reinforcing patterns on the first mounting surface of the insulating substrate comprising conductivity, the reinforcing patterns extending from an outer periphery of the fiduciary marker toward outside of the fiduciary marker and being located circumferentially at intervals relative to the fiduciary marker, the reinforcing patterns comprising a width shorter than an outer periphery of the fiduciary marker configured to connect to adjacent reinforcing patterns, one of the adjacent reinforcing patterns configured to electrically connect to the first conductive through hole;
a first conductive layer on the first mounting surface of the insulating substrate, the first conductive layer being away from the fiduciary marker and configured to electrically connect to the second conductive through hole; and
a second conductive layer on the second mounting surface of the insulating substrate, the second conductive layer is configured to electrically connect the first conductive through hole to the second conductive through hole.

15. The printed wiring board of claim 14, wherein a reinforcing pattern in the reinforcing patterns and corresponding to the first conductive through hole comprises a land configured to electrically connect to the first conductive through hole.

16. The printed wiring board of claim 14, wherein the second conductive layer comprises lands configured to electrically connect to the first conductive through hole and the second conductive through hole.
